(19) United States
(12) Patent Application Publication
(10) Pub. No.: US 2009/0189292 A1
(43) Pub. Date: Jul. 30, 2009

(54) Integrated Circuit, Semiconductor Module and Method for Manufacturing a Semiconductor Module

(76) Inventors: Martin Reiss, Dresden (DE); Knut Kahlisch, Dresden (DE); Joerg Keller, Dresden (DE)

Correspondence Address: SLATER & MATSIL, L.L.P., 17950 PRESTON ROAD, SUITE 1000, DALLAS, TX, 75252, US

(21) Appl. No.: 12/021,943

(22) Filed: Jan. 29, 2008

(51) Int. Cl. H01L 21/58; H01L 23/49

(52) U.S. Cl. 257/777; 438/109; 257/E23.024; 257/E21.505

(57) ABSTRACT

Embodiments of the invention relate to a semiconductor, a semiconductor module and to a method for manufacturing a semiconductor module. In an embodiment of the invention, an integrated circuit includes a plurality of connection pads on at least one side of the integrated circuit, which connection pads can be coupled electrically conductingly by means of a respective bond wire, wherein in at least an edge area on the side of the integrated circuit, on which the connection pads are arranged, a support frame portion is arranged which is configured such that bond wires adjacent to each other can be supported on the support frame portion at a distance from each other.

### TECHNICAL FIELD

Embodiments of the invention relate to an integrated circuit, a semiconductor module and to a method for manufacturing a semiconductor module.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic view of a semiconductor arrangement according to an embodiment of the invention arranged on a substrate;

FIG. 2 shows a partial sectional view of a semiconductor arrangement according to the embodiment shown in FIG. 1;

FIG. 3 shows a partial sectional view of another semiconductor arrangement according to an embodiment of the invention;

FIG. 4 shows a side view of a semiconductor arrangement according to an embodiment of the invention, arranged on a substrate;

FIG. 5 shows a partial sectional view of a semiconductor module according to an embodiment of the invention;

FIG. 6 shows a partial sectional view of another semiconductor module according to an embodiment of the invention in an intermediate state;

FIG. 7 shows a schematic view of a semiconductor module according to another embodiment of the invention; and

FIG. 8 shows a partial sectional view of a semiconductor module according to an embodiment of the invention.

### DETAILED DESCRIPTION OF ILLUSTRATIVE EMBODIMENTS

In this description the terms “connected”, “linked” and “coupled” are used for describing a direct connection as well as an indirect connection, a direct link or indirect link and a direct coupling or an indirect coupling. In the Figures, identical or similar elements are provided with identical reference numbers, inasmuch as this is appropriate.

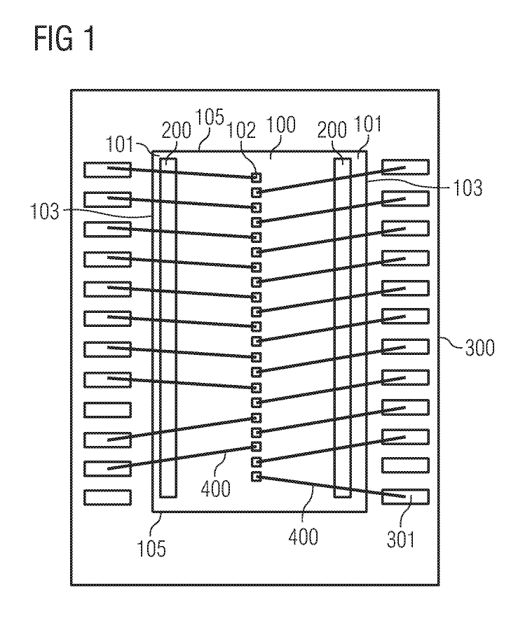

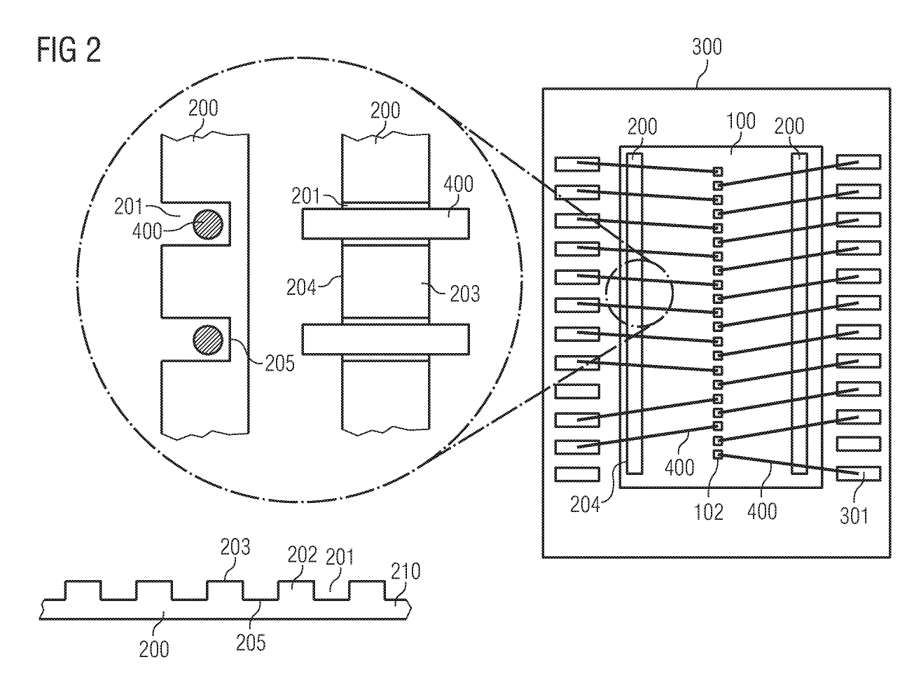

In FIG. 1 a schematic view of a semiconductor arrangement according to an embodiment of the invention arranged on a substrate is shown, whereas FIG. 2 shows a partial sectional view of the semiconductor according to the embodiment shown in FIG. 1.

In FIG. 1 an integrated circuit 100 is shown with a plurality of connection pads 102 on at least one side of the integrated circuit 100, which connection pads 102 can be coupled electrically conductingly by means of a bond wire 400 each, wherein in at least an edge area 101 on the side of the integrated circuit 100, on which the connection pads 102 are arranged, a support frame portion 200 is arranged for fixing the bond wires 400 in its original position. For example, the support frame portion 200 can be configured such that bond wires 400 adjacent to each other can be supported at a distance from each other on the support frame portion 200 in that position in which the bond wires are arranged during the bond process.

The integrated circuit 100 can, for example, be a semiconductor chip which is, for example, configured as a memory chip. By the term “integrated circuit” also a die or a wafer may be understood according to other embodiments of the invention.

In the integrated circuit 100 shown in FIG. 1, for example, in the form of a semiconductor chip, the connection pads 102 are, for example, arranged in the area along a longitudinal center region of the semiconductor chip. Although only one row of connection pads 102 is shown herein, the connection pads can, for example, also be arranged in several rows one after the other or laterally shifted and one after the other. In this embodiment, two support frame portions 200 are arranged on the upper side, i.e., on the so-called active side of the, for example, semiconductor chip 100, respectively one of which extends in one of the two edge areas 101 of the semiconductor chip, the direction of extension of the two support frame portions 200 being oriented substantially in parallel to the longitudinal center region along which the connection pads 102 are arranged. The support frame portions 200 have, for example, a long narrow shape and extend next to the chip edges 103 almost until the two free edges 105 running perpendicular to the chip edges 103.

In the embodiment shown in FIG. 1 the semiconductor chip (i.e., the integrated circuit 100) is arranged on a carrier 300. The carrier 300 may, for example, be a printed circuit board (PCB), a BGA substrate, a lead frame or the like. However, the carrier 300 may also be an integrated circuit in the form of a semiconductor chip, which can, for example, be electrically conductingly coupled with the semiconductor chip 100, if desired. On the side of the carrier 300 facing the semiconductor chip 100 a plurality of contact pads 301 are provided, which, according to this embodiment, are arranged next to the corresponding peripheral edges (the chip edges 103) of the semiconductor chip 100, in the edge area of which the support frame portions 200 are positioned. The connection pads 102 of the semiconductor chip 100 are each connected electrically conductingly to a contact pad 301 of the carrier 300 by means of a bond wire 400, wherein it can be seen that according to this embodiment a part of the bond wires 400 can extend over the support frame portion 200 arranged on the right-hand side in the illustration, and a part of the bond wires 400 can extend over the support frame portion 200 arranged on the left-hand side in the illustration to the contact pads 301 on the carrier 300.

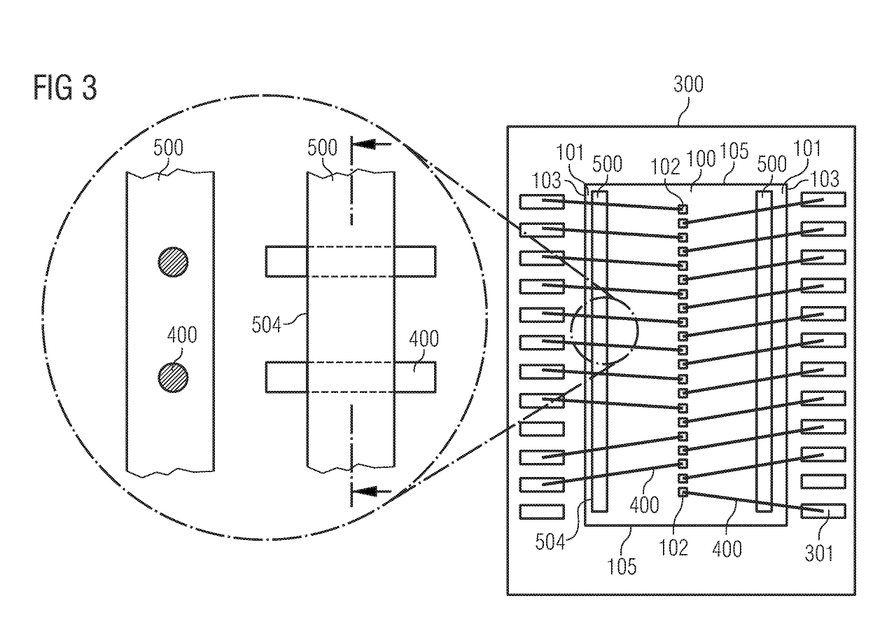

In an integrated circuit according to an embodiment which is not shown, the connection pads 102 can also be arranged to be distributed on an upper side of the integrated circuit 100, for example, in the form of a square instead of being arranged in the area along a longitudinal center region. In such an embodiment, unlike in the illustration according to FIG. 1, a support frame portion 200 (500) can respectively be arranged in the area of each edge 105 in addition to the support frame portions 200 (500, FIG. 3) in the area of each edge 103. Thereby, the bond wires can extend starting from the connection pads arranged, for example, in the form of a square, supported on one of the four support frame portions, to the corresponding contact pads of another mounting level, wherein by another mounting level also another integrated circuit can be meant which is arranged next to, above or beneath the integrated circuit, which can be electrically coupled with the integrated circuit.

As can be seen from FIG. 2, the support frame portion 200 can be a strip-shaped layer applied to the integrated circuit 100, which includes a plurality of channels 201 arranged in a bonding direction and being open upwards, into which respectively one bond wire 400 can be inserted. The support frame portion 200 may, for example, be a structured tape 210 adhered to the integrated circuit 100, which includes on its free upper side the channels 201 arranged next to each other and being open upwards, which extend in the direction of the bond wires 400 to be arranged. In this regard, the support frame portion 200 includes at least such a number of channels 201 which correspond to the number of the wires to be bonded.

The support frame portion 200 can, for example, also be manufactured on a wafer level, wherein instead of applying a structured tape to the integrated circuit 100 in the form of a chip or die the desired support frame portions 200 can, for example, be manufactured by application, deposition or the like of non-conducting material to the wafer, which material is processed by means of a standardized photo resist technology such that in the end the support frame portions 200 remain as a strip-shaped structure on corresponding portions of the wafer, in which in addition also the channels 201 are formed. Thereby, the support frame portions can be provided on the dice to be processed already before singulating the wafer into dice.

The upper sides 203 of the wall portions 202 which delimit the channels 201, being substantially in one level, are each formed to be plane according to this embodiment. This means that in the embodiment according to FIG. 2, wherein at least two support frame portions 200 are arranged on an integrated circuit 100, the support frame portions 200 are additionally configured for supporting another integrated circuit, as will be explained later.

Finally, during the bonding process the bond wires 400 are first attached, for example, to the connection pads 102 (the contact surfaces) of the semiconductor chip 100, for example, by means of fusing or pressure welding of the wire end. Then, the wire loop is formed by means of a bonding tool, for example, such that the bond wire 400, oriented to the correspondingly assigned channel 201, is drawn or guided to the predetermined contact pad 301 on the carrier 300 and is subsequently attached there, for example, by fusing or pressure welding. In this regard, the tracking of the bond wire 400 from the bonding tool takes place, for example, such that the bond wire 400 is sunk or guided or inserted in the corresponding channel 201. A conventional bonding method can be used for the wire bonding, such as thermocompression bonding, thermosonic bonding, and ultrasonic bonding.

As can be seen from FIG. 2, the channels 201 may be formed to be deeper than the bond wire 400 is thick, according to this embodiment. However, for a semiconductor module using only one integrated circuit 100 according to an embodiment of the invention it is also possible that the channels are, for example, respectively only as deep (not shown) as the bond wires 400, for example, sunk into the respective channel 201, only with half of their cross-section. This is sufficient for respectively holding the single bond wires steadily so that the bond wires 400 are prevented from contacting each other, for example, in a subsequent molding process.

By supporting or holding bond wires 400 adjacent to each other by means of the support frame portion 200 respectively at a distance from each other on the support frame portion 200, it is ensured that the bond wires 400 cannot contact each other, such that short-circuits due to contacts between the bond wires 400 are avoided. If, for example, a semiconductor module includes an integrated circuit 100 according to an embodiment, in which the bond wires 400 are steadily held at a distance from each other by means of the support frame portion 200, it can be ensured, for example, in a subsequent molding process that a sweeping of the bond wires 400 caused by mold flow is avoided. In the production of packages of that type, conventional molding processes can be used, since a contacting of the bond wires held at a distance from each other cannot take place during the molding process. From this it follows that the yield loss of packages in which an integrated circuit 100 according to an embodiment of the invention is used can be reduced. In addition, when using an integrated circuit 100 according to an embodiment of the invention, bond wires can be used which are thinner than usual, whereby the costs for a package can be reduced, because the support frame portion 200 acts as a mechanical wire sweep protection for the thinner bond wires 400. In addition, the use of thinner bond wires involves the advantage that electrical cross talk behavior is improved, i.e., reduced.

In FIG. 3 a partial sectional view of another semiconductor arrangement according to an embodiment of the invention is shown.

Similarly, according to the embodiment of FIG. 2, two support frame portions 500 are arranged on the integrated circuit 100 in the embodiment shown in FIG. 3 as well. The two support frame portions 500 are also respectively located in the edge area 101 of the two edges 103, beyond which the bond wires 400 are extending from the connection pads 102 of the integrated circuit 100 to the corresponding contact pads 301 on the structural element of the next mounting level, such as, for example, a carrier 300 or an adjacent integrated circuit (not shown).

The support frame portions 500 according to this embodiment of the invention are each formed by a strip-shaped layer of a B-stage adhesive, into which the bond wires 400 can be pressed at least in part during the bonding process. The B-stage adhesive applied to the integrated circuit 100 is, for example, in an uncured or un-crosslinked state before the bonding of the bond wires 400 and has, for example, a pasty texture. In addition, the B-stage adhesive can, for example, have such a viscosity that the B-stage adhesive maintains its shape after application to the integrated circuit 100 and is not capable of flowing. Applying the B-stage adhesive to the integrated circuit 100 in the form of a strip-shaped layer can, for example, be carried out by means of adhesive dispensing or by means of stencil printing or by means of another suitable application method.

During the bonding process the bond wires 400 are first attached, for example, to the connection pads 102 (the contact surfaces) of the semiconductor chip 100, for example, by means of fusing or pressure welding of the wire end. This is followed by forming the wire loop by means of a bonding tool, for example, in such a manner that the bond wire 400 is drawn or guided to the predetermined contact pad 301 on the carrier 300 and subsequently attached thereto, for example, by fusing or pressure welding. In this regard, the tracking of the bond wire 400 from the bonding tool is carried out, for example, in such a manner that, after the bonding tool having passed the support frame portion 500, i.e., after the bonding tool having been guided over the support frame portion 500, the bond wire 400 is tightened or held short in such a manner that the bond wire 400 is pressed into the layer of B-stage adhesive forming the support frame portion 500. It shall be understood that in this embodiment the texture of the support frame portion 500 formed by B-stage adhesive is such that a pushing-in of the bond wires 400 is ensured. A conventional bonding method can be used for wire bonding, such as thermocompression bonding, thermosonic bonding, ultrasonic bonding, etc.

Due to the fact that at first the B-stage adhesive is soft and, for example, uncured, the respective bond wire can be easily pressed into the adhesive during the bonding process, wherein the adhesive properties, such as the flowing behavior are, for example, set such that the adhesive layer closes above the bond wires after the bond wires 400 having been pushed in. From the enlarged view in FIG. 3 it can be seen that according to an embodiment of the invention, the bond wires 400 are entirely surrounded by adhesive in the region of the support frame portions 500 formed by B-stage adhesive, i.e., are embedded in the adhesive.

Depending on which bonding method is used for bonding the bond wires 400, an increased temperature can be used during the bonding process, which acts on the integrated circuit 100 as well as on the carrier 300. This may, for example, lead to the B-stage adhesive starting to harden into a half-cured state (B-stage) due to the increased temperature. Otherwise it is also possible to subject a so-called semiconductor module having, for example, the integrated circuit 100, the carrier 300 and the bond wires 400 pressed into the support frame portion 500 made of B-stage adhesive to a pre-determined heat treatment, and in doing so to cure the B-stage adhesive into the B-stage, in which the adhesive is not fully cured yet. Already in this half-cured state the bond wires 400 are held so steadily at a distance from each other by the support frame portion 500 that the bond wires 400 are entirely or in part prevented from moving within the adhesive.

In addition, the support frame portion 500 arranged on the integrated circuit 100 is suitable for serving as a spacer for another integrated circuit to be mounted onto the integrated circuit 100, and is at the same time configured as an adhesive or holding means for the other integrated circuit. In an embodiment of the invention, this means concretely that another integrated circuit placed on the support frame portion 500 of the integrated circuit 100 can be adhesively held by the support frame portion 500. If, for example, a predetermined pressure is applied to the other integrated circuit supported on the support frame portion 500 under heat supply, and if the other integrated circuit is pressed in the direction toward the integrated circuit 100, the half-cured adhesive can be partially melted in a controlled manner and can finally form an adhesive connection with the lower side of the other integrated circuit. If the other integrated circuit is designed in the form of the integrated circuit 100, yet another integrated circuit can be arranged on the other integrated circuit after the bonding of the same, and so on. By a subsequent complete curing (C-stage) of the B-stage adhesive by, for example, subjecting the stack of integrated circuits, for example, to a predetermined heat treatment, on the one hand the bond wires embedded in the adhesive are unremovably fixed and on the other hand the adhesive connection between the support frame portion 500 and the integrated circuit positioned thereon becomes unremovably stable.

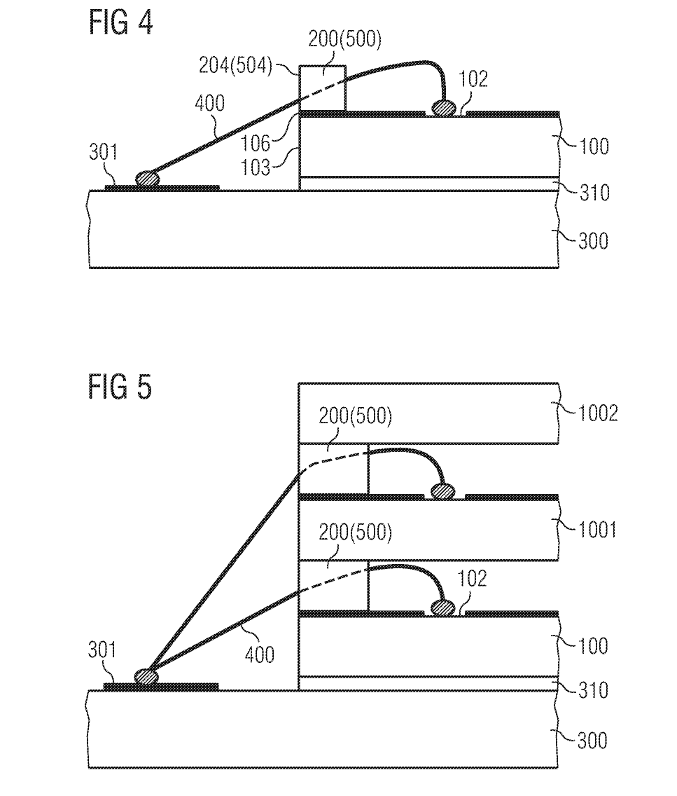

FIG. 4 shows a side view of a semiconductor arrangement according to an embodiment of the invention, arranged on a substrate.

FIG. 4 shows an integrated circuit 100 arranged on a carrier 300, which is, for example, attached to the carrier 300 by means of an adhesive layer 310. On the upper side of the integrated circuit 100 facing away from the carrier 300, for example, a support frame portion 200, the embodiment of which has been discussed on the basis of FIG. 2, or a support frame portion 500, the embodiment of which has been explained on the basis of FIG. 3, is arranged in an edge area. In the embodiment according to FIG. 4 the support frame portion 200 (500) is arranged in the edge area of the integrated circuit 100 such that a longitudinal edge 204 (504) of the support frame portion 200 (500) is almost flush with the peripheral edge 103 of the integrated circuit 100. As can further be seen from FIG. 4, the connection pads 102 (only one is shown) of the integrated circuit 100 are electrically conductingly coupled with a contact pad 301 of the carrier 300 respectively by means of a bond wire 400, wherein the bond wires 400 are each supported on the support frame portion 200 (500) such that bond wires 400 which are adjacent to each other cannot contact each other (see also FIG. 2 and FIG. 3).

Due to the fact that the bond wires 400 are guided through the channels 201, such as in the embodiment according to FIG. 2, that the channels 201 each include a channel bottom 205 and that the support frame portion 200 is arranged in the edge area of the integrated circuit 100, the bond wires 400 are furthermore held by the support frame portion 200 in such a manner that the bond wires 400 are prevented from contacting a peripheral edge 106 of the integrated circuit 100 and thus from additionally contacting the integrated circuit 100 at all. A risk occurring in a subsequent conventional molding process, according to which the very fine bond wires 400 can on the one hand be pressed against each other or can be pressed in the direction of the peripheral edge of the integrated circuit due to the mold flow, is at least reduced with an integrated circuit 100 with a support frame portion 200 (500) according to an embodiment of the invention and is even excluded in one embodiment of the invention.

As already explained, just as in the manufacturing of the embodiment according to FIG. 3, the bond wires 400 are guided during the bonding process in such a predetermined manner, that the bond wires are pressed either in part or entirely into the support frame portion 500 being arranged in the form of a layer of B-stage adhesive, wherein the arrangement of the bond wires 400 is carried out in such a manner that the bond wires do not contact the peripheral edge 106 of the integrated circuit 100. In an embodiment of the invention, concretely, this means that the forming of the wire loop is carried out in such a controlled manner that the bond wires 400 are, for example, pressed up to the center of the layer of B-stage adhesive (500), but that the bond wires 400 are prevented from being pressed into the adhesive layer entirely through the layer of B-stage adhesive to the upper side of the integrated circuit 100. In addition, due to the fact that the B-stage adhesive is half-cured, i.e., crosslinked into the B-stage either already due to the heat generated during the bonding process or during a curing process following the bonding, the bond wires 400 are held by and in the support frame portion 500, respectively, and are prevented from being able to move or to contact each other.

FIG. 5 shows a partial sectional view of a semiconductor module according to an embodiment of the invention.

The arrangement shown in FIG. 5, which can, for example, be a multi-chip package (MCP), includes a carrier 300 and an integrated circuit 100 which is, for example, attached to the carrier 300 by means of an adhesive layer 310. The configuration of the integrated circuit 100, the carrier 300 and the bond wires 400, for example, corresponds to the embodiment of a semiconductor module explained by means of FIG. 4, wherein the integrated circuit 100, for example, includes two support frame portions 200 (500) which are arranged on edge portions of the integrated circuit 100 facing each other, as shown in FIG. 2 and FIG. 3.

As it can further be seen from FIG. 5, a first further integrated circuit 1001 is arranged on the integrated circuit 100 of the semiconductor module according to the embodiment explained in FIG. 4. After the connection pads 102 of the integrated circuit 100 having been electrically conductingly connected to contact pads 301 of the carrier 300 by means of bond wires 400 such that the bond wires 400 are held and supported, respectively, by means of the support frame portion 200 (500) at a distance from each other, another integrated circuit 1001 is positioned onto the support frame portions 200 (500), only one of which is shown in this illustration. The other integrated circuit 1001 can substantially be formed like the integrated circuit 100.

If the integrated circuit 100 is, for example, provided with two support frame portions 200 each having a plurality of channels opened upwards and aligned in the bonding direction, into which respectively one bond wire 400 can be inserted (see FIG. 2), the adhering of the other integrated circuit 1001 on and to the support frame portions 200, respectively, can, for example, be achieved by the plane upper side 203 of the wall portions 202 delimiting the channels 201 being each configured to be adhesive, by the plane upper sides 203 being, for example, provided with an adhesive layer and an adhesive film, respectively, or, for example, by adhesive being applied to the support portions 200 following the wire bonding, which can flow into the channels 201 in the area of the channels 201, but which however remains adhered to the upper side 203 of the wall portions.

However, it is also possible to carry out the adhering of the other integrated circuit 1001 to the support frame portion 200, for example, by means of a direct die attach film (DDAF) (not shown in FIG. 4), which is arranged on the lower side of the other integrated circuit 1001 facing the support frame portions 200, such that providing an additional adhesive layer on the support frame portions 200 can be omitted. It is also possible to provide on the side of the other integrated circuit 1001 facing the support frame portions 200 an adhesive layer at least in the area of the support frame portions 200, which adhesive layer is suitable for forming an adhesive connection with the free upper sides 203 of the wall portions delimiting the channels. The mentioned adhesive layer may for example be a B-stage adhesive.

Following the wire bonding of the other integrated circuit 1001, for example, with the carrier 300, yet another integrated circuit 1002 can be positioned on and attached in the previously described manner to the other integrated circuit 1001 which is substantially formed like the integrated circuit 100 described with regard to FIG. 5. Due to the described embodiment, the support frame portions 200, 500 not only serve for steadily holding the bond wires at a distance from each other but at the same time also as spacers for a next upper integrated circuit in a stack.

If the integrated circuit 100, for example, includes two support frame portions 500 each formed by a layer of a B-stage adhesive, the bond wires 400 are pressed into the support frame portions 500, i.e., into the adhesive layer or are rather entirely surrounded by adhesive in the area of the support frame portions 500, as described by means of the embodiment according to FIG. 3. The B-stage adhesive used for this embodiment is set such that the B-stage adhesive is in the B-stage (half-cured) after bonding, such that the support frame portions 500 (layer of adhesive) are mechanically stable so that another integrated circuit 1001 can be positioned onto the support frame portions 500 without any change of the form of the support frame portions 500. By applying a predetermined force to the other integrated circuit 1001 under the influence of heat, the half-cured B-stage adhesive which still includes its adhesive properties can partially melt, i.e., can be transferred into a state of plastical deformability and form an adhesive connection with the lower side of the other integrated circuit 1001.

After the wire bonding of the other integrated circuit 1001 then having been terminated and after the partial hardening of the layer of B-stage adhesive of the other integrated circuit 1001 forming the support frame portions 500 having taken place, yet another integrated circuit 1002 can be arranged on the other integrated circuit 1001 and can finally be provided with bond wires which can be pressed into the corresponding support frame portions 500. Thereby, a semiconductor module can be formed with a desired number of integrated circuits stacked upon each other, wherein the support frame portions 500 of each integrated circuit do not only serve for steadily holding the bond wires 400 at a distance from each other but at the same time also serve as spacers for a next upper integrated circuit in a stack, and can in addition be configured as an adhesive means, such that consequently no additional application of adhesive to the support frame portions or to the integrated circuit itself is necessary for attaching a next integrated circuit.

This means that the described support frame portions 200, 500 attached to an integrated circuit not only serve for steadily holding the bond wires at a distance from each other but at the same time also serve as distance-keeping supports for a next upper integrated circuit in a stack.

In addition, the integrated circuits according to an embodiment of the invention, which on their one side include support frame portions 200 or support frame portions 500, can, for example, be stacked at a distance of, for example, between about 10 μm and about 200 μm between respectively two integrated circuits arranged on top of each other in a stack, because the bond wires of the respectively lower integrated circuit are held and protected within the support frame portions 200 or 500.

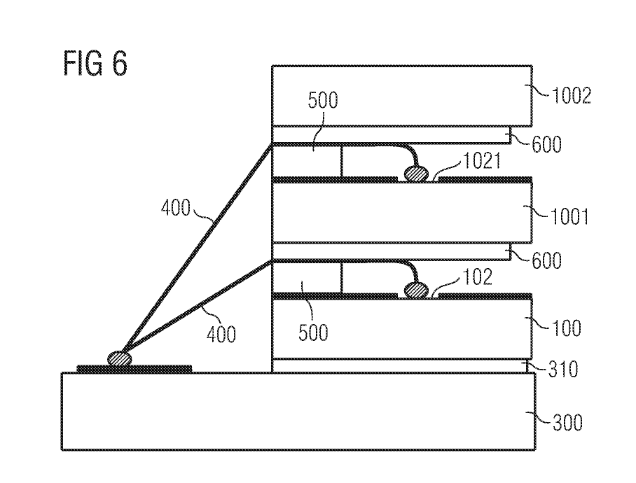

FIG. 6 shows a partial sectional view of another semiconductor module according to an embodiment of the invention in an intermediate state.

In FIG. 6 a semiconductor module is schematically shown in an intermediate mounting state, in which at first, for example, by means of an adhesive layer 310 a first integrated circuit 100 according to an embodiment of the invention is attached, for example, in the form of a semiconductor chip to a carrier 300. The integrated circuit 100 includes on its active upper side facing away from the carrier the connection pads 102 (only one shown). In addition, for example, in two edge areas of the integrated circuit 100 facing each other respectively one support frame portion 500 (only one shown) is arranged, which can, for example, extend along the entire corresponding edge of the integrated circuit 100. The support frame portions 500 are each formed by a long narrow layer of B-stage adhesive. In the intermediate state shown the support frame portions 500, i.e., the B-stage adhesive, are already half-cured according to this embodiment, i.e., the adhesive is in the B-stage.

From FIG. 6 it can further be seen that in the intermediate mounting state shown the bond wires 400 extend from the connection pads 102 of the integrated circuit 100 to the contact pads of the carrier 300 beyond the support frame portions 500, i.e., at this time, they are not pressed into the support frame portions 500 yet. Another integrated circuit 1001 is arranged on the integrated circuit 100, which is supported on the support frame portions 500. In the embodiment shown a layer 600 is arranged on the lower side of the other integrated circuit at least in the area of the support frame portions 500, which is, for example, configured to be adhesive. This layer 600 may, for example, be a direct die attach film (DDAF) which is, for example, made of a material which, for example, can melt partially under the influence of pressure and heat, and which can consequently deform plastically. However, the layer 600 can also simply be an adhesive layer which has been applied, for example, by means of a printing process or by means of an adhesive spin-on on the inactive side of the other integrated circuit 1001. After positioning the other integrated circuit 1001 on the support frame portions 500, the bond wires 400 are first arranged between the support frame portions 500 and the layer 600, as shown. If finally a force is applied to the other integrated circuit 1001 from the top under predetermined temperature conditions, the support frame portions 500 of B-stage adhesive can melt partially, such that the bond wires 400 are pressed into the support frame portions 500 at least in part (not shown in FIG. 6). If the layer 600 includes a partially meltable material, it is in addition possible for the support frame portions 500 of B-stage adhesive as well as for the layer 600 to melt partially, such that the bond wires 400 are pressed, for example, in part into the support frame portions 500 and in part into the layer 600. By the partial melting the adhesive properties of the B-stage adhesive are activated and an adhesive connection is formed between the integrated circuit 100 and the other integrated circuit 1001. The partial pressing of the bond wires 400 into the adhesive layer 600 is possible even if the adhesive of the adhesive layer is relatively soft and can be deformed plastically in a relatively easy way.

After the adhesive connection has been effected, the connection pads 1021 of the other integrated circuit 1001 which is, for example, provided with exactly such support frame portions 500 as the integrated circuit 100, can, for example, be electrically conductingly coupled with contact pads of the carrier, for example, by arranging bond wires 400, by the bond wires first being arranged beyond the support frame portions 500 of the other integrated circuit 1001. Subsequently, yet another integrated circuit 1002 can be arranged on the other integrated circuit 1001, which, for example, also is provided on its lower side with a layer 600 which is, for example, configured to be adhesive. By applying a predetermined force to the temporarily positioned still other integrated circuit 1002 and under the influence of a predetermined temperature the support frame portions 500 of the other integrated circuit 1001 or the support frame portions 500 of the other integrated circuit and the layer 600 can melt partially, such that the bond wires 400 are either pressed into the support frame portions 500 or partially into the support frame portions 500 and partially into the layer 600.

A final curing of the B-stage adhesive can take place by the semiconductor module including the desired number of integrated circuits 100, 1001, 1002, . . . , for example, arranged on each other being subject to a last curing step in which at least the B-stage adhesive, by which the support frame portions 500 are formed on the integrated circuit, is entirely crosslinked into its C-stage, i.e., is entirely cured.

A semiconductor module which is, for example, formed according to the embodiment described by means of FIG. 5 and/or FIG. 6 and which includes at least two integrated circuits 100, 1001, . . . which are arranged on each other, which are adhesively connected to each other in the area of the support frame portions 200, 500 by means of an adhesive connection, can subsequently be processed by means of an actually conventional casting process, for example, by means of an injection molding process for manufacturing a package including at least the integrated circuits and the bond wires 400. In this process, the integrated circuits to be ensheathed with mold compound, including the bond wires 400 can, for example, be received in a casting mold which is filled with a mold compound. Due to the fact that, for example, every single bond wire 400 is held on and by the support frame portion 200 and 500, respectively, at a distance from a respectively adjacent bond wire 400, the bond wires 400 are protected against deflection or moving towards each other even if the mold compound is injected into the casting mold at a basically usual pressure. For manufacturing a package around an integrated circuit according to an embodiment of the invention it is consequently not necessary to use a specifically adapted mold compound which is configured for a very slow insertion (for example, injection) into the casting mold.

Due to the fact that the bond wires 400 used for the electrical connection in accordance with various embodiments of the invention are held on the support frame portions, as a consequence bond wires can be used which are thinner than bond wires in conventional integrated circuits, because these bond wires 400 are steadily supported or held in an area between the one attachment to the contact pads 102 of the integrated circuit 100 (1001, 1002, . . . ) and the other attachment to the contact pads of another mounting level, such as the carrier 300. For example, the support frame portions 200, 500 can be arranged on the integrated circuit in such a manner that the, for example, substantially strip-shaped support frame portions 200, 500 extend approximately in the center between, for example, a row of connection pads 102 on the integrated circuit and, for example, a row of contact pads next to the integrated circuit, to which the bond wires 400 are connected. The use of bond wires 400 which are, for example, thinner than usual, can, for example, have the advantage that the bond wires 400 themselves can be arranged at a smaller distance from each other, such that more connections of an integrated circuit than usual can be electrically conductingly coupled respectively by means of bond wires, whereby consequently the connection density can be increased and whereby as a result an integrated circuit with an increased performance can be provided at reduced costs. In addition, with an integrated circuit according to an embodiment of the invention the loss of yield can be reduced for example by the reduction of the problems leading to leakage. The support frame portions 200 and 500, respectively, are each made of a non-conducting material.

The use of an integrated circuit 100 according to an embodiment of the invention is, for example, suitable for chip designs, wherein the connection pads are arranged in a center area or rather along a longitudinal center region of the integrated circuit 100, because in this case relatively long bond wires are supported on a support frame portion 200 (500). A cost-intensive conventional redistribution of the connection pads 102 into edge areas of the integrated circuit, for example, by means of a redistribution layer to be capable of making the required length of the bond wires shorter, is consequently not necessary anymore with an integrated circuit 100 according to an embodiment of the invention. The use of an integrated circuit 100 with the support frame portions 200 (500) according to an embodiment of the invention has, for example, a positive effect for MCPs with several semiconductor chips arranged one upon the other, because as the stack height increases the length of the bond wires increases as well, the bond wires of every single stacked semiconductor chip being supported on the corresponding support frame portion, though.

Due to the fact that the bond wires are held by means of the support frame portions during, for example, a subsequent mold process, not only is it ensured that they cannot contact each other, but it is in addition also ensured that between bond wires adjacent to each other a distance is maintained also in the area between, for example, the connection pads and the support frame pads, which is such that even those short-circuits can be avoided which conventionally could not be determined in a burn-in and test and which, for example, took place only with the customer due to long-term load of the integrated circuit and which lead to breakdowns.

The integrated circuit with a support frame portion in at least an edge area according to an embodiment of the invention is suitable for a one-chip package as well as for a multi-chip package, in which the bond wires are held on a mechanical guidance, the support frame portions, and are therefore protected against short-circuits due to contacts between bond wires. This holding or rather supporting of the bond wires at a distance from each other furthermore enables the use of bond wires which are thinner than usual.

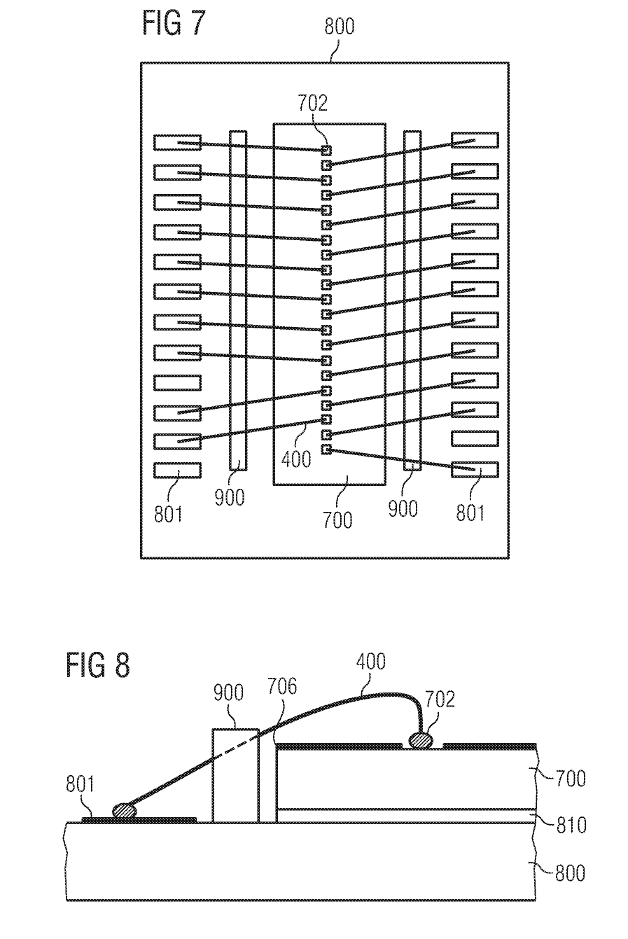

FIG. 7 shows a schematic view of a semiconductor module according to another embodiment of the invention; and FIG. 8 shows a partial sectional view of a semiconductor module according to an embodiment of the invention.

In the embodiment according to FIG. 7 and FIG. 8, an integrated circuit 700 which is, for example, formed as a semiconductor chip is attached to a carrier 800 by means of an adhesive layer 810 and includes on its upper side showing away from the carrier 800 a plurality of connection pads 702 which are, for example, arranged in the area along a longitudinal center region of the semiconductor chip 700. On the carrier 800 a plurality of contact pads 801 are arranged on two sides next to the semiconductor chip 700. Between the edge on the right-hand side in the illustration and the edge on the left-hand side in the illustration of the semiconductor chip 700 and the correspondingly assigned two rows of contact pads 801 on the carrier 800 a strip-shaped support frame portion 900 extends respectively, on which the bond wires 400 respectively extending, for example, from respectively one of the connection pads 702 to respectively one of the contact pads 801 are supported and held at a distance from each other.

The support frame portions 900 can, for example, be formed each by a tape in which a plurality of channels (not shown) opened upwards and oriented in a bonding direction are formed, into which respectively one bond wire 400 is inserted, or rather through which channels respectively one bond wire is guided. In this regard, the channels are, for example, designed to be deep enough (not shown) that a bond wire 400 guided through a channel is prevented, for example, from contacting the corresponding edge 706 of the semiconductor chip 700 even if the bond wire 400 contacts the bottom of the channel. Instead of a tape, for example, attached to the carrier 800, the support frame portions 900 can also be formed by another stable structure of non-conducting material including the channels, as long as the number of the channels formed in the support frame structures 900 suffices to receive the number of bond wires corresponding to the chip design in such a manner that they cannot contact each other. If the semiconductor module according to FIG. 7 and according to FIG. 8 is subsequently provided, for example, by means of injection molding with a package, the bond wires are prevented from coming close to each other due to the mold flow that they might contact each other. With the discussed arrangement, short-circuits due to undesired bond wire contacts may be prevented from taking place. Furthermore, due to the fact that the bond wires 400 are held on the support frame portions 900, bond wires 400 can be used for bonding which are thinner than usual, whereby an improved connection rate is possible and whereby in addition a cost reduction is achieved.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An electronic device, comprising:
an integrated circuit;
a plurality of connection pads on at least one side of the integrated circuit;
bond wires attached to the connection pads; and
a support frame portion at at least one edge area on the at least one side of the integrated circuit with the connection pads, the support frame portion fixing the bond wires in a predetermined position.

2. The electronic device according to claim 1, wherein the support frame portion is formed such that the bond wires are prevented from contacting a peripheral edge of the integrated circuit.

3. The electronic device according to claim 1, wherein the support frame portion comprises electrically non-conducting material.

4. The electronic device according to claim 1, wherein the support frame portion is further configured for supporting another integrated circuit above the integrated circuit.

5. The electronic device according to claim 1, wherein the support frame portion comprises a strip-shaped layer applied to the integrated circuit, the strip-shaped layer comprising a plurality of channels oriented in a bonding direction and being open upwards such that a bond wire can be inserted in each channel.

6. The electronic device according to claim 5, wherein the support frame portion comprises a tape formed with the channels.

7. The electronic device according to claim 1, wherein the support frame portion is formed by a strip-shaped layer of a B-stage adhesive, into which the bond wires can be pressed at least in part during a bonding process.

8. The electronic device according to claim 1, wherein the support frame portion is formed by a strip-shaped layer of a B-stage adhesive, into which the bond wires can be pressed at least in part after a bonding process by applying pressure and heat.

9. The electronic device according to claim 1, wherein the support frame portion is respectively arranged on edge portions facing each other.

10. The electronic device according to claim 1, wherein the integrated circuit comprises a semiconductor chip.

11. The electronic device according to claim 1, wherein the integrated circuit is a semiconductor chip;
wherein the connection pads are arranged in an area along a longitudinal center region; and
wherein respectively a strip-shaped support frame portion extends in an area of two edges of the semiconductor chip, which extend in parallel to the longitudinal center region.

12. A semiconductor module comprising a carrier and an integrated circuit which is arranged on the carrier, wherein the integrated circuit comprises a plurality of connection pads on a side facing away from the carrier;
the carrier comprises a plurality of contact pads arranged next to the integrated circuit on the carrier; and
a plurality of bond wires, wherein the connection pads of the integrated circuit are electrically conductingly connected to the contact pads of the carrier respectively by means of the bond wires;
wherein in at least an edge area on a side of the integrated circuit facing away from the carrier a support frame portion is arranged, on which bond wires adjacent to each other are held at a distance from each other.

13. The semiconductor module according to claim 12, wherein the support frame portion comprises a strip-shaped layer comprising a plurality of channels oriented in a bonding direction and being open upwards;
wherein each of the bond wires is guided through one of the channels.

14. The semiconductor module according to claim 12, wherein the support frame portion is a strip-shaped layer of a B-stage adhesive, wherein the bond wires are surrounded at least in part in the area of the support frame portion.

15. The semiconductor module according to claim 12, wherein the support frame portion is a strip-shaped layer of a B-stage adhesive, wherein the bond wires are entirely surrounded in the area of the support frame portion.

16. The semiconductor module according to claim 12, wherein the support frame portion is in addition configured for supporting another integrated circuit to be arranged above the integrated circuit.

17. The semiconductor module according to claim 12, further comprising another integrated circuit supported on the support frame portion of the integrated circuit, the another integrated circuit being adhesively held by the support frame portion.

18. The semiconductor module according to claim 12, further comprising another integrated circuit supported on the support frame portion of the integrated circuit, the another integrated circuit being configured with an adhesive layer on its side facing the support frame portion.

19. The semiconductor module according to claim 14, further comprising another integrated circuit supported on the support frame portion of the integrated circuit, the another integrated circuit being configured with an adhesive layer on its side facing the support frame portion.

20. The semiconductor module according to claim 19, wherein the bond wires are at least in part pressed into the adhesive layer of the other integrated circuit.

21. A semiconductor module comprising a carrier and an integrated circuit arranged on the carrier, wherein the integrated circuit comprises a plurality of connection pads on a side facing away from the carrier;
wherein the carrier comprises a plurality of contact pads adjacent the integrated circuit on the carrier;
wherein the connection pads of the integrated circuit are electrically conductingly connected by a respective bond wire to the contact pads of the carrier; and
wherein a support frame portion is arranged between a peripheral edge of the integrated circuit and the contact pads on the carrier, by means of which the bond wires adjacent to each other are held at a distance from each other and are prevented from contacting the peripheral edge of the integrated circuit.

22. A method for manufacturing a semiconductor module, the method comprising:
arranging an integrated circuit on a carrier, wherein the integrated circuit comprises a plurality of connection pads on a side facing away from the carrier and wherein the carrier comprises a plurality of contact pads adjacent the integrated circuit;
disposing a support frame portion over the integrated circuit, wherein the support frame portion is located in at least an edge area on the side on which the connection pads are disposed, the support frame portion comprising a strip-shaped layer of an adhesive; and
wire bonding the connection pads on the integrated circuit with the contact pads of the carrier in such a manner that bond wires are pressed, at least in part, into the strip-shaped layer of the adhesive during the bonding process.

23. The method according to claim 22, wherein the adhesive comprises a B-stage adhesive and wherein a hardening of the strip-shaped layer of B-stage adhesive into the B-stage takes place during the wire bonding process.

24. The method according to claim 22, wherein the adhesive comprises a B-stage adhesive, the method further comprising arranging another integrated circuit on the support frame portion after a first curing of the support frame portion, the another integrated circuit being arranged on the support frame portion by applying heat and pressure.

25. A method for manufacturing a semiconductor module, the method comprising:
arranging an integrated circuit on a carrier, wherein the integrated circuit comprises a plurality of connection pads on a side facing away from the carrier and wherein the carrier comprises a plurality of contact pads adjacent the integrated circuit;
arranging a support frame portion adjacent an edge area on the side on which the connection pads are arranged, the support frame portion comprising a strip-shaped layer of a B-stage adhesive;
wire bonding the connection pads on the integrated circuit with the contact pads of the carrier, wherein the bond wires are arranged on the strip-shaped layer of the B-stage adhesive; and
arranging another integrated circuit on the support frame portion and applying a force to an upper side of the other integrated circuit under predetermined temperature conditions, such that the bond wires are at least in part pressed into the support frame portion and such that the support frame portion forms an adhesive connection with the other integrated circuit.
